(19) United States
(12) Patent Application Publication
(10) Pub. No.: US 2010/0148356 A1
(43) Pub. Date: Jun. 17, 2010

(54) STACKED SEMICONDUCTOR DEVICE AND MANUFACTURING METHOD THEREOF

(75) Inventor: Tomohiro TAMAKI, Osaka (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/711,658

(22) Filed: Feb. 24, 2010

Related U.S. Application Data
(63) Continuation of application No. PCT/JP2009/002626, filed on Jun. 10, 2009.

(30) Foreign Application Priority Data
Oct. 31, 2008 (JP) 2008-280803

(51) Int. Cl. H01L 23/34; H01L 21/50

(52) U.S. Cl. 257/712; 438/107; 257/E23.08; 257/E21.499

(57) ABSTRACT

A semiconductor device includes: a first substrate; a second substrate provided over the first substrate, and divided into a plurality of portions; a cooling member provided in a gap between the divided second substrate portions on the first substrate; and a third substrate provided on the second substrate portions and the cooling member. For example, a heat pipe or the like is used as the cooling member.

### CROSS-REFERENCE TO RELATED APPLICATION

This is a continuation of PCT International Application PCT/JP2009/002626 filed on Jun. 10, 2009, which claims priority to Japanese Patent Application No. 2008-280803 filed on Oct. 31, 2008. The disclosures of these applications including the specifications, the drawings, and the claims are hereby incorporated by reference in their entirety.

### BACKGROUND

A technique disclosed in the present specification relates to heat dissipating mechanisms of semiconductor devices in which semiconductor integrated circuit substrates are vertically stacked.

Examples of a stacked semiconductor device in which semiconductor elements are vertically stacked by using through electrodes, bump electrodes, or thin metal wires are described in Japanese Published Patent Application Nos. 2008-177241 and 2007-096279. FIGS. 7 and 8 are cross-sectional views respectively showing conventional semiconductor devices in which a plurality of semiconductor elements are vertically stacked.

A stacked semiconductor device of a first conventional example shown in FIG. 7 includes: a resin substrate 106; a silicon interposer 103 placed over the resin substrate 106 via bumps 104; a first semiconductor element 101 provided on the silicon interposer 103; a second semiconductor element 102 provided on the first semiconductor element 101; a heat dissipating plate 108 attached to the back surface of the resin substrate 106; and metal balls 107 made of solder, and provided on the back surface of the resin substrate 106. The first semiconductor element 101 is, e.g., a logic LSI (Large Scale Integration) circuit, and the second semiconductor element 102 is, e.g., a memory LSI circuit. The first semiconductor element 101 and the second semiconductor substrate 102 may or may not be provided with through electrodes (not shown). The resin substrate 106 and the silicon interposer 103, the silicon interposer 103 and the first semiconductor element 101, and the first semiconductor element 101 and the second semiconductor substrate 102 may be connected together either via bumps, or via thin metal wires (not shown).

Recently, increased operating speed and pin count of LSI circuits have increased heat generation, resulting in a growing need to efficiently dissipate heat to the outside of semiconductor elements. In particular, logic LSI circuits tend to generate a large amount of heat. In the stacked semiconductor device of the first conventional example shown in FIG. 7, a part of the heat dissipating plate 108 having a T-shaped cross section is in contact with a region that reaches the highest temperature in the first semiconductor element 101. Heat is transmitted through the heat dissipating plate 108 vertically downward with respect to the substrate surface of the first semiconductor element 101, and is dissipated to the back surface of the resin substrate 106. The heat dissipation path is indicated by an arrow in FIG. 7.

FIG. 8 is a cross-sectional view of a stacked semiconductor device according to a second conventional example. In this stacked semiconductor device, a plurality of recesses are formed in the upper surface of a silicon interposer 103, and the recesses are filled with a metal material to form a heat dissipating plate 108.

### SUMMARY

However, the above examples of the related art have the following problems.

Due to an increase in the number of LSI chips that are stacked, and ever-increasing heat generation of the LSI circuits, it is becoming increasingly difficult to sufficiently dissipate heat in conventional stacked semiconductor devices. Thus, problems such as a malfunction of an LSI circuit are more likely to occur due to the high temperature. There is a need for a structure for efficiently cooling a so-called hot spot 105 (see FIG. 7), which reaches the relatively highest temperature in the LSI circuit. In order to increase the amount of heat dissipation in the semiconductor device of the first conventional example shown in FIG. 7, it is possible to place a heat pipe vertically, instead of the heat dissipating plate 108. However, the heat pipe includes a heat absorbing portion and a heat dissipating portion, and needs to be long enough to circulate a working fluid. Thus, the length of the heat pipe is typically several to several tens of times the diameter thereof. For example, if the diameter of the heat pipe is 1 mm, the length thereof needs to be, e.g., at least several millimeters. This is larger than the sum of the respective thicknesses of the silicon interposer 103, the resin substrate 106, and the bumps 104. Thus, the heat pipe extends through the resin substrate 106, which requires a through hole to be formed in the resin substrate 106 and a motherboard (not shown) over which the resin substrate 106 is placed. Accordingly, it is difficult to implement a structure having such a heat pipe. If the respective thicknesses of the silicon interposer 103, the resin substrate 106, and the bumps 104 are 500 μm, 600 μm, and 50 μm, respectively, the heat dissipation path is about 1.150 mm.

In the conventional stacked semiconductor devices, a stress generated by the difference in thermal expansion coefficient between the silicon interposer 103 and the resin substrate 106 can bend the substrate, thereby reducing connection reliability of the bumps 104.

In the stacked semiconductor device of the first conventional example, since the heat dissipating plate 108 is placed on the back surface of the resin substrate 106, a through hole needs to be formed in the resin substrate 106 as well. This reduces an interconnect region of the resin substrate 106, and thus, reduces the number of metal balls 107, thereby making it difficult to apply the stacked semiconductor device to applications requiring a higher pin count.

A stacked semiconductor device according to an example of the present invention can efficiently dissipate heat, which is generated inside the stacked semiconductor device, without reducing the pin count.

A stacked semiconductor device according to an example of the present invention includes: a first substrate; a second substrate provided over the first substrate, and divided into a plurality of portions; a cooling member provided in a gap between the divided second substrate portions on the first substrate; and a third substrate provided on the second substrate portions and the cooling member.

According to this configuration, the cooling member is placed under the third substrate. Thus, heat, which is generated in an LSI circuit or the like, can be effectively dissipated. Since the cooling member is provided on the first substrate, it is not necessary to form a hole in the first substrate, enabling a multiplicity of external connection terminals to be placed. Since the second substrate is divided into a plurality of portions, the influence of a stress that is applied between the first substrate and the second substrate portions can be reduced as compared to the case where the second substrate is not divided, whereby bending of the substrate can be reduced.

It is preferable that the cooling member have a heat absorbing portion and a heat dissipating portion, and that a region that reaches a highest temperature (a hot spot) in the third substrate be located at the same position as that of the heat absorbing portion, since the heat can be especially effectively dissipated.

For example, a heat pipe is preferably used as the cooling member.

A method for manufacturing a stacked semiconductor device according to an example of the present invention includes the steps of: (a) placing a plurality of second substrates over a first substrate with a gap between the plurality of second substrates; (b) providing a cooling member in at least a part of the gap between the plurality of second substrates on the first substrate; and (c) placing a third substrate on the plurality of second substrates and the cooling member.

According to this method, the cooling member is placed under the third substrate. Thus, heat, which is generated in an LSI circuit or the like, can be effectively dissipated. Since the cooling member is provided on the first substrate, there is no need to form a hole in the first substrate, enabling a multiplicity of external connection terminals to be placed. Since a plurality of second substrates are placed with a gap therebetween, the influence of a stress that is applied between the first substrate and the second substrates can be reduced as compared to the case where only one second substrate having no gap is placed, whereby bending of the substrate can be reduced.

The stacked semiconductor device according to an example of the present invention can alleviate or prevent malfunctions of an LSI circuit due to a high temperature, and can ensure a sufficient amount of heat dissipation even if heat generation of the LSI circuit is further increased. This stacked semiconductor device also enables a so-called hot spot, which reaches a relatively high temperature in the LSI circuit, to be efficiently cooled. Moreover, this stacked semiconductor device can reduce a stress, which is generated in the case where substrates having different thermal expansion coefficients from each other, such as a silicon interposer and a resin substrate, are connected together. Thus, bending of the substrate can be reduced, whereby connection reliability of connecting members, such as bumps, can be increased. Since the number of external connection terminals, which are provided on the first substrate, can be increased as compared to conventional structures, the stacked semiconductor device of the present invention can be used in applications requiring a higher pin count.

### BRIEF DESCRIPTION OF THE DRAWINGS

FIG. 1 is a cross-sectional view of a stacked semiconductor device according to a first embodiment of the present invention.

FIG. 2 is a perspective view of the stacked semiconductor device of the first embodiment.

FIG. 3 is a perspective view of a stacked semiconductor device according to a second embodiment of the present invention.

FIG. 4 is a plan view of a stacked semiconductor device according to a third embodiment of the present invention.

FIG. 5 is a plan view of a stacked semiconductor device according to a modification of the third embodiment.

FIGS. 6A, 6B, 6C, and 6D are cross-sectional views of a stacked semiconductor device according to a fourth embodiment of the present invention.

FIG. 7 is a cross-sectional view of a conventional semiconductor device in which a plurality of semiconductor elements are vertically stacked.

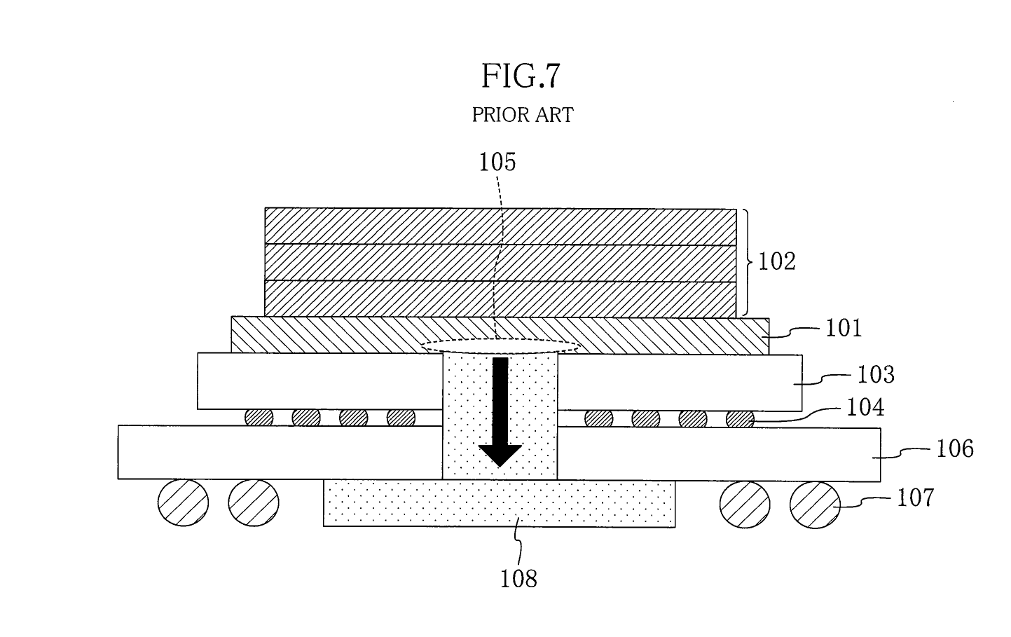

FIG. 8 is a cross-sectional view of a conventional semiconductor device in which a plurality of semiconductor elements are vertically stacked.

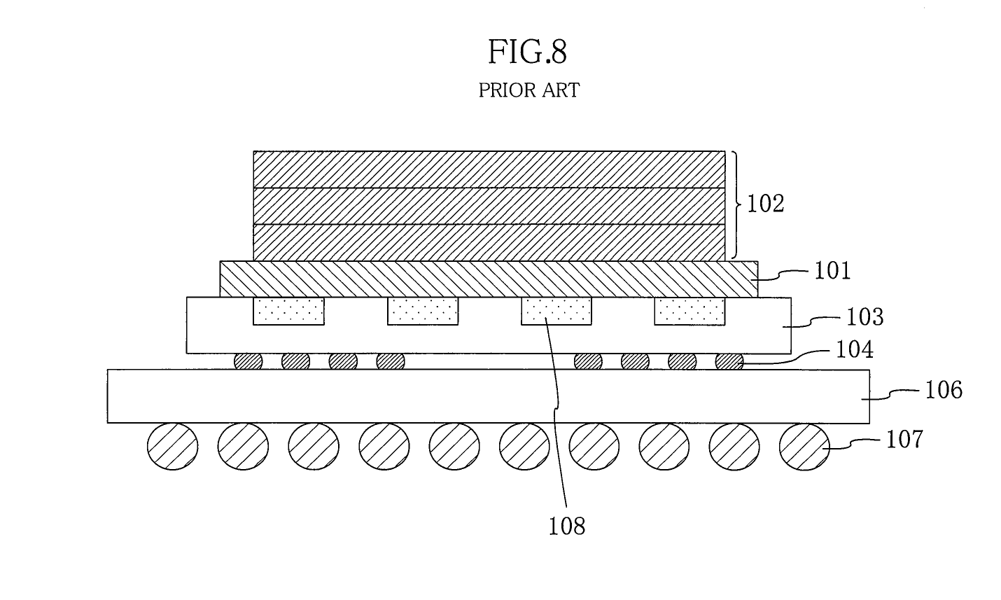

### DETAILED DESCRIPTION

### First Embodiment

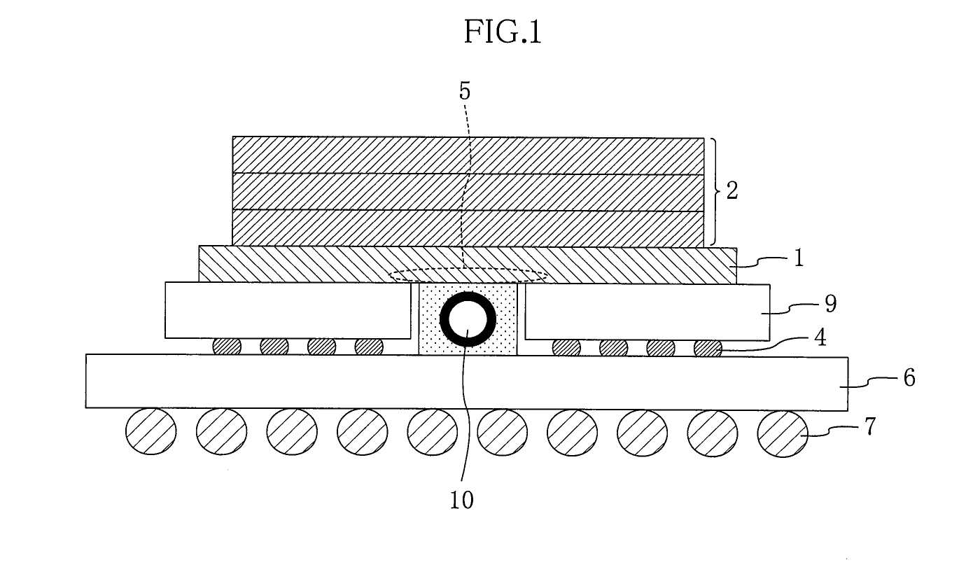

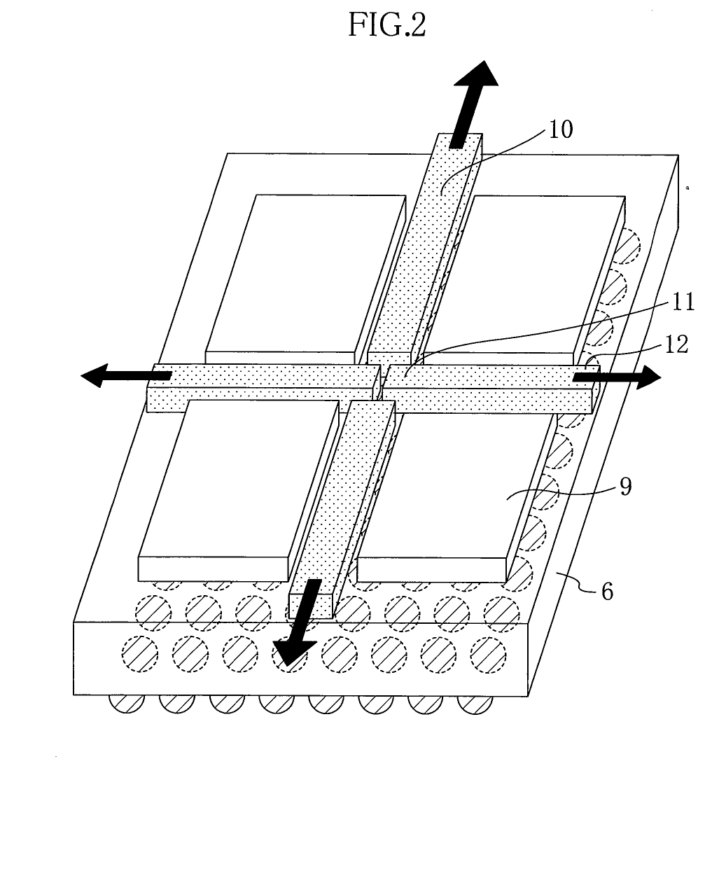

FIG. 1 is a cross-sectional view of a stacked semiconductor device according to a first embodiment of the present invention. FIG. 2 is a perspective view of the stacked semiconductor device of the first embodiment.

As shown in FIGS. 1 and 2, the stacked semiconductor device of the present embodiment includes a resin substrate (a first substrate) 6, a silicon interposer (a second substrate) 9, a first semiconductor element (a third substrate) 1, a second semiconductor element 2, and metal balls 7. The silicon interposer 9 is placed over the upper surface of the resin substrate 6 via bumps 4 made of, e.g., solder, and is divided into a plurality of portions (four portions in this embodiment; hereinafter these divided portions are referred to as the “silicon interposer portions 9”). The first semiconductor element 1 is provided on the silicon interposer portions 9, and the second semiconductor element 2 is provided on the first semiconductor element 1. The metal balls 7 are provided on the back surface of the resin substrate 6. For example, a plurality of semiconductor chips are vertically stacked in the second semiconductor element 2. The first semiconductor element 1 is, e.g., a logic LSI circuit, and the second semiconductor element 2 is, e.g., a memory LSI circuit, or the like.

The central region of the first semiconductor element 1 is a hot spot 5 where a larger amount of heat is generated as compared to the surrounding region. Heat generation of the LSI circuit has been increased due to an increase in operating speed and pin count. A heat pipe (a cooling member) 10 is provided in each of the gaps between the four silicon interposer portions 9, and each heat pipe 10 extends from immediately below the hot spot 5 toward a corresponding end of the resin substrate 6. The heat pipes 10 are produced by, e.g., forming a hollow member of a highly thermally conductive material such as a metal, evacuating the hollow member, and injecting a liquid therein.

As shown in FIG. 2, respective heat absorbing portions 11 of the heat pipes 10 are placed at the intersection of the dividing lines that separate the silicon interposer portions 9 from each other (on the central region of the resin substrate 6), and respective heat dissipating portions 12 of the heat pipes 10 are respectively provided at the ends of the resin substrate 6. Providing the hot spot 5 of the LSI circuit (the first semiconductor element 1) and the heat absorbing portions 11 of the heat pipes 10 at the same position enables heat, which is generated in the first semiconductor element 1 and the second semiconductor element 2, to be efficiently dissipated. The heat dissipation path is indicated by arrows in FIG. 2.

A total of four heat pipes 10 may be respectively placed in the gaps between the silicon interposer portions 9. Alternatively, at least one heat pipe 10 may be placed in at least one of the gaps between the plurality of silicon interposer portions 9, and a heat dissipating material may be placed in the other gaps. The heat dissipating material may be a copper plate, an aluminum plate, or a highly thermally conductive resin.

The heat pipes 10 have a circular cross section in FIG. 1. However, the heat pipes 10 may have a quadrangular, elliptical, rectangular, or other cross section. In the case where the heat pipes 10 have a circular cross section, the diameter of the heat pipes 10 is about several hundreds of micrometers to about 3 mm.

The heat pipes 10 may or may not extend outward beyond the ends of the plurality of silicon interposer portions 9. As shown in FIG. 2, placing the respective heat dissipating portions 12 of the heat pipes 10 at the ends of the resin substrate 6, respectively, significantly increases the temperature difference between the heat absorbing portion 11 and the heat dissipating portion 12, whereby heat dissipation efficiency can be increased.

The inside of the heat pipes 10 is kept under vacuum, and the heat pipes 10 are filled with a working fluid. As described above, each heat pipe 10 has a heat absorbing portion 11 and a heat dissipating portion 12. When the heat absorbing portion 11 is heated, the working fluid in the heat pipe 10 evaporates, and the vapor stream flows into the heat dissipating portion 12 having a lower atmospheric pressure. In the heat dissipating portion 12, the vapor condenses into a liquid, which circulates to the heat absorbing portion 11. The heat is transferred in this manner. The working fluid is repeatedly subjected to evaporation, condensation, and circulation, whereby the heat is dissipated with high heat conductivity.

According to the above configuration, since the heat pipes 10 having high heat dissipation efficiency are placed under the first semiconductor element 1 (especially the hot spot 5), heat generated in the first semiconductor element 1 can be efficiently dissipated to the outside, alleviating or preventing problems such as malfunctions due to overheating of the semiconductor elements. The heat pipes 10 extend in a direction parallel to the substrate surface of the silicon interposer portions 9 (or the first semiconductor element 1). Thus, there is no need to form a hole in the resin substrate 6 even if the heat pipes 10 are long, thereby facilitating manufacturing. Moreover, since the number of metal balls 7, which serve as external connection terminals (connection terminals for connection to external equipment), can be increased as compared to the case where a heat dissipating plate is provided on the back surface of the resin substrate 6, this stacked semiconductor device can be used in applications requiring a higher pin count. Since the silicon interposer 9 is divided into a plurality of portions, a stress, which is generated by the difference in thermal expansion coefficient between the silicon interposer 9 and the resin substrate 6, can be reduced. Thus, bending of the substrate (the silicon interposer portions 9 and the resin substrate 6) can be reduced, and connection reliability of the bumps 4 can be increased.

When manufacturing the stacked semiconductor device of the present embodiment, the plurality of silicon interposer portions 9 are first placed over the resin substrate 6 with a gap between the silicon interposer portions 9. At this time, the silicon interposer portions 9 are aligned as appropriate, and placed over the resin substrate 6. Next, the bumps 4 are melted by a heat treatment to connect the resin substrate 6 with the silicon interposer portions 9. Then, the heat pipes 10 are respectively placed in the gaps between the silicon interposer portions 9. Subsequently, the first semiconductor element 1 and the second semiconductor element 2 are sequentially placed over the silicon interposer portions 9 and the heat pipes 10. It is preferable to place the first semiconductor element 1 so that the hot spot 5 and the respective heat absorbing portions 11 of the heat pipes 10 are located at the same position.

Although FIGS. 1 and 2 show an example in which the silicon interposer portions 9 are used as a substrate, a substrate that is interposed between the first semiconductor device 1 and the resin substrate 6 may be made of a material such as silicon, a resin, ceramic, or a metal.

The silicon interposer portions 9 are typically a substrate having only an interconnect pattern formed thereon. However, the silicon interposer portions 9 may be replaced with, e.g., a substrate provided with semiconductor elements such as memory LSI circuits or logic LSI circuits. In that case, a total of four memory LSI circuits or logic LSI circuits are placed over the resin substrate 6, the first semiconductor element 1 is placed on the memory or logic LSI circuits, and the second semiconductor element 2 is placed on the first semiconductor element 1.

Through electrodes (not shown) may be provided in the resin substrate 6 and the silicon interposer portions 9, in the silicon interposer portions 9 and the first semiconductor element 1, and in the first semiconductor element 1 and the second semiconductor element 2, and the resin substrate 6 and the silicon interposer portions 9, the silicon interposer portions 9 and the first semiconductor element 1, and the first semiconductor element 1 and the second semiconductor element 2 may be connected together via the bumps 4. Alternatively, the resin substrate 6 and the silicon interposer portions 9, the silicon interposer portions 9 and the first semiconductor element 1, and the first semiconductor element 1 and the second semiconductor element 2 may be connected together by thin metal wires (not shown).

Note that, as described below, the silicon interposer 9 need not necessarily be divided into four portions. The silicon interposer 9 may be divided into any number of portions as long as the respective heat absorbing portions 11 of the heat pipes 10 can be placed immediately below the hot spot 5.

### Second Embodiment

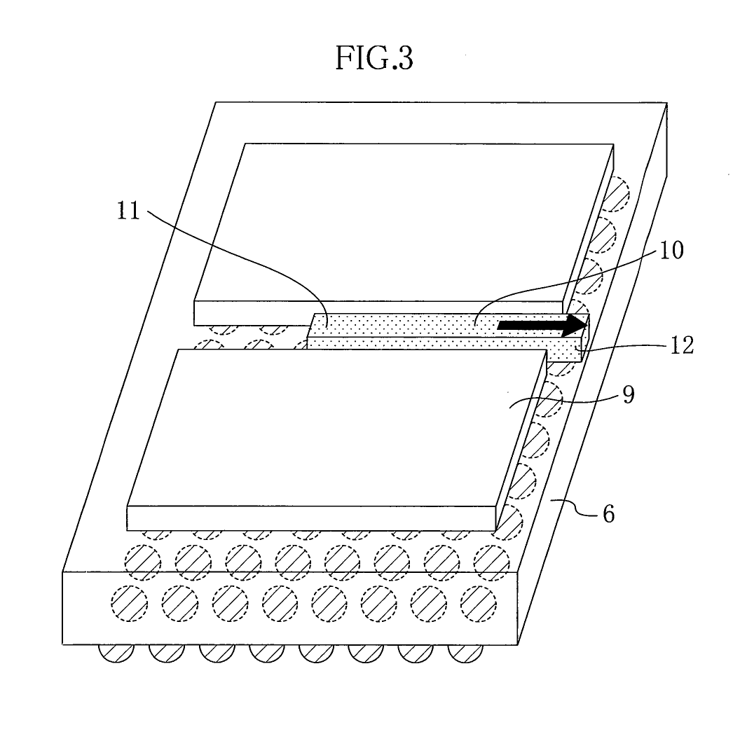

FIG. 3 is a perspective view of a stacked semiconductor device according to a second embodiment of the present invention. In FIG. 3, the same members as those of FIGS. 1 and 2 are denoted by the same reference characters, and description thereof will be simplified or omitted.

In the stacked semiconductor device of the present embodiment, a silicon interposer 9 is divided into two portions (hereinafter these divided portions are referred to as the “silicon interposer portions 9”). A heat pipe 10 is provided in the gap between the two silicon interposer portions 9. A hot spot 5 of an LSI circuit such as a first semiconductor element, and a heat absorbing portion 11 of the heat pipe 10 are located at the same position. This enables heat generated in the LSI circuit to be efficiently dissipated. The heat dissipation path is indicated by an arrow in FIG. 2.

The heat pipe 10 may or may not extend outward beyond the ends of the plurality of silicon interposer portions 9, as shown in FIG. 2. A heat dissipating portion 12 of the heat pipe 10 may extend to an end of the resin substrate 6. Placing the heat dissipating portion 12 of the heat pipe 10 at the end of the resin substrate 6 significantly increases the temperature difference between the heat absorbing portion 11 and the heat dissipating portion 12, whereby heat dissipation efficiency can be increased.

### Third Embodiment

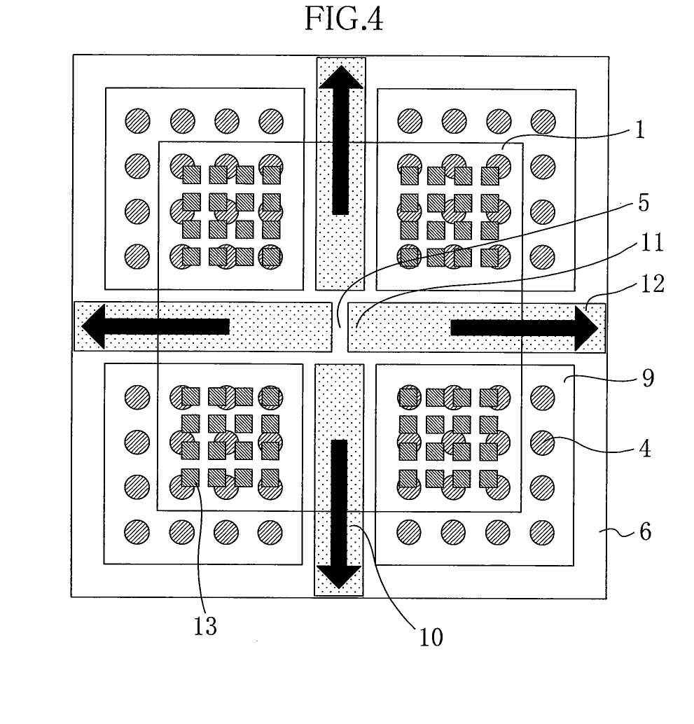

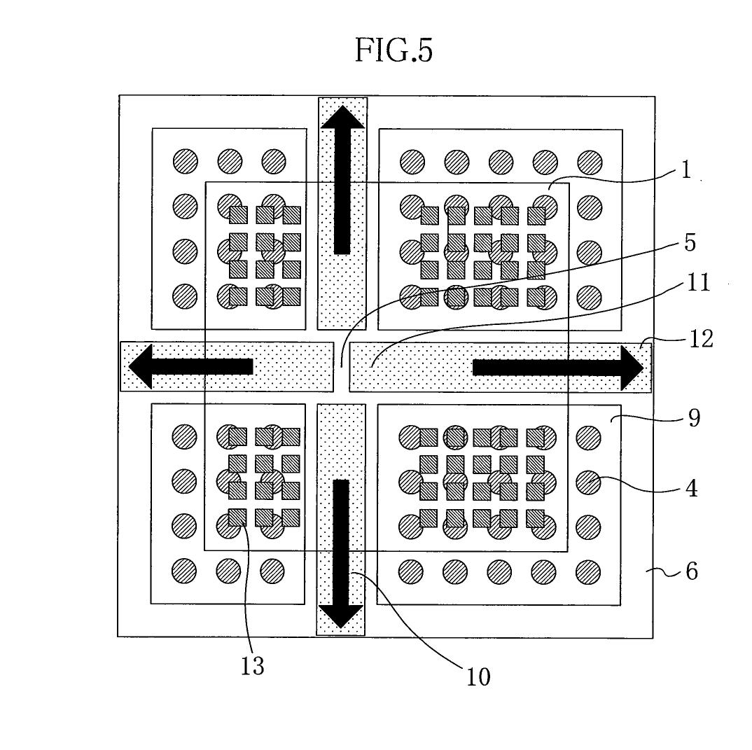

FIG. 4 is a plan view of a stacked semiconductor device according to a third embodiment of the present invention. FIG. 5 is a plan view of a stacked semiconductor device according to a modification of the third embodiment. To facilitate understanding, components such as the first semiconductor element 1 are shown as transparent in FIGS. 4 and 5.

As shown in FIG. 4, in the semiconductor device of the present embodiment, a silicon interposer 9 is divided into a plurality of portions (hereinafter these divided portions are referred to as the “silicon interposer portions 9”). The plurality of silicon interposer portions 9, and a first semiconductor element 1 are sequentially vertically stacked over the resin substrate 6. A second semiconductor element 2 is stacked on the first semiconductor device, but is not shown in FIG. 4 for clarity.

In FIG. 4, the silicon interposer 9 is equally divided into four portions. That is, the four divided small substrates of the silicon interposer 9 have the same size. Note that, in the modification of FIG. 5, the silicon interposer 9 is unequally divided into four portions (hereinafter these divided portions are referred to as the “silicon interposer portions 9”).

Heat pipes 10 are respectively provided in the gaps between the plurality of silicon interposer portions 9. A total of four heat pipes 10 may be respectively placed in the gaps between the plurality of silicon interposer portions 9. Alternatively, at least one heat pipe 10 may be placed in at least one of the gaps between the plurality of silicon interposer portions 9, and a heat dissipating material may be placed in the other gaps. The heat dissipating material may be a copper plate, an aluminum plate, or a highly thermally conductive resin.

Respective heat absorbing portions 11 of the heat pipes 10 are placed at the intersection of the dividing lines that separate the plurality of silicon interposer portions 9 from each other. A hot spot 5 of the first semiconductor element 1 and the respective heat absorbing portions 11 of the heat pipes 10 need not necessarily be accurately located at the same position. However, it is preferable to locate the hot spot 5 and the heat absorbing portions 11 at the same position, because heat can be dissipated more efficiently. The heat dissipation path is indicated by arrows in FIG. 4.

In the stacked semiconductor device of the present embodiment shown in FIG. 4, the intersection of the dividing lines that separate the plurality of silicon interposers 9 from each other is positioned in the center of the first semiconductor element 1. In this case, heat dissipation efficiency is increased if the hot spot 5 of the first semiconductor element 1 is positioned in the center of the first semiconductor element 1. However, the heat dissipation efficiency can be reduced if the hot spot 5 is offset from the center of the first semiconductor element 1.

In the modification of FIG. 5, the intersection of the dividing lines that separate the plurality of silicon interposer portions 9 from each other is intentionally offset from the center of the first semiconductor element 1, and the hot spot 5 of the first semiconductor element 1 and the respective heat absorbing portions 11 of the heat pipes 10 are substantially accurately located at the same position. This can significantly increase the heat dissipation efficiency.

Each terminal 13 of the first semiconductor element 1 is connected to a corresponding one of the plurality of silicon interposer portions 9. This connection is made by a flip-chip method or the like. The terminals 13 of the first semiconductor element 1 are connected to the resin substrate 6 via the plurality of silicon interposer portions 9 and the bumps 4.

In the stacked semiconductor devices shown in FIGS. 4 and 5, the plurality of terminals 13 of the first semiconductor element 1 are arranged in a two-dimensional pattern. No terminal 13 is formed at the positions respectively corresponding to the gaps between the silicon interposer portions 9. That is, no terminal 13 is formed on the heat pipes 10.

Specifically, when designing the first semiconductor element 1, the position of the hot spot 5 is predicted in advance, and arrangement of the terminals 13 of the first semiconductor element 1 is designed so that the hot spot 5 and the respective heat absorbing portions 11 of the heat pipes 10 are located at the same position. That is, the respective positions of the terminals 13 of the first semiconductor device 1 are determined so that no terminal 13 of the first semiconductor element 1 is located on the heat pipes 10. In other words, when designing arrangement of the terminals 13 of the first semiconductor element 1 in a two-dimensional pattern, the position of the hot spot 5 is predicted in advance, so that no terminal 13 of the first semiconductor element 1 is located on the dividing lines that separate the silicon interposer portions 9 from each other, including on the hot spot 5.

### Fourth Embodiment

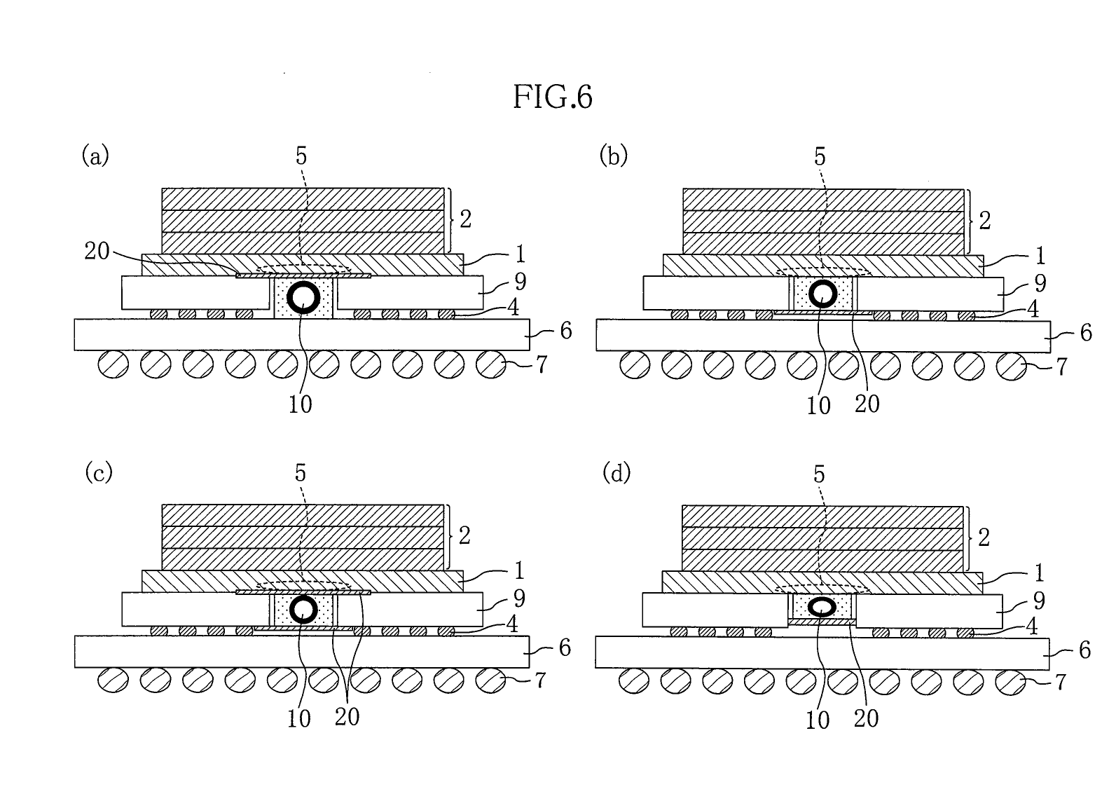

FIGS. 6A-6D are cross-sectional views of a stacked semiconductor device according to a fourth embodiment of the present invention. As shown in these figures, the stacked semiconductor device of the present embodiment is different from the stacked semiconductor device of the first embodiment shown in FIG. 1 in that adjoining ones of the silicon interposer portions (second substrate portions) 9, which adjoin each other with a corresponding one of the heat pipes (the cooling members) 10 interposed therebetween, are coupled together by, e.g., a plate-like coupling portion. The differences from the stacked semiconductor device of the first embodiment will be described below.

In an example of the stacked semiconductor device shown in FIG. 6A, the respective upper surfaces of adjoining ones of the silicon interposer portions 9 are coupled together by a coupling portion 20.

In the case of using a single silicon interposer 9 having a groove (a recess) formed therein, this coupling portion 20 may be a part of the silicon interposer 9, which remains after formation of the groove (the recess) in the silicon interposer 9. The groove may be formed by, e.g., cutting or etching the silicon interposer 9.

Alternatively, the coupling portion 20 may extend over the entire region where the plurality of silicon interposer portions 9 are placed. That is, the plurality of silicon interposer portions 9 may be placed on a single sheet or a flat plate having substantially the same area as the total area of the plurality of silicon interposer portions 9. In this case, providing through interconnects (not shown) in the coupling portion 20 enables a stacked structure to be implemented without hindering connection of the bumps 4 or the like.

In the case of using, e.g., a multilayer interconnect substrate that is made of an insulating resin, instead of the silicon interposer portions 9, a single-layer region, where no multilayer interconnect is formed, can be used as the coupling portion 20.

This coupling portion 20 has, e.g., a plate shape having a thickness of about several tens of micrometers to about 100 μm. Thus, the coupling portion 20 hardly affects the overall thickness of the stacked semiconductor device. In the case where the coupling portion 20 is a part of a single silicon interposer 9, which remains after formation of a groove (a recess) in the silicon interposer 9, the coupling portion 20 does not affect an increase in overall thickness of the stacked semiconductor device at all.

The material of the coupling portion 20 is not specifically limited. However, if the coupling portion 20 is made of an insulator such as a resin, interconnects or through interconnects can be provided on the coupling portion 20, whereby design flexibility can be increased.

The material of the coupling portion 20 may be a conductive resin, or may be silicon, ceramic, a metal, or the like.

Since the silicon interposer portions 9 are coupled together by the coupling portion 20, the mechanical strength of the stacked semiconductor device can be increased.

As shown in FIG. 6B, the coupling portion 20 may be provided to couple the respective lower surfaces of adjoining ones of the silicon interposer portions 9 to each other. Alternatively, as shown in FIG. 6C, the coupling portion 20 may be provided to couple both the respective upper surfaces and the respective lower surfaces of adjoining ones of the silicon interposer portions 9 to each other. In the case where the coupling portion 20 couples the respective lower surfaces of adjoining ones of the silicon interposer portions 9 to each other, interconnects can be provided on the lower surface of the coupling portion 20.

As shown in FIG. 6D, the coupling portion 20 may couple the respective side surfaces of adjoining ones of the silicon interposer portions 9 to each other. In this case as well, interconnects can be provided on the lower surface of the coupling portion 20.

Note that, in the case where the coupling portion 20 couples the respective upper surfaces or the respective lower surfaces of the silicon interposer portions 9, the planar shape and the planar area of the coupling portion 20 are not limited as long as the coupling portion 20 does not hinder connection of the bumps 4 or the like. Alternatively, even if the coupling portion 20 extends over the entire region where the plurality of silicon interposer portions 9 are placed, providing through interconnects (not shown) in the coupling portion 20 enables a stacked structure to be implemented without hindering connection of the bumps 4 or the like.

The configuration shown in FIG. 6A is implemented by, e.g., respectively placing the heat pipes 10 in the gaps between the silicon interposer portions 9 in the manufacturing process of the first embodiment, and then, placing the coupling portion 20, which extends over the heat pipes 10 and couples the respective upper surfaces of the silicon interposer portions 9. Then, the first semiconductor element 1 and the second semiconductor element 2 are sequentially placed over the silicon interposer portions 9.

The stacked semiconductor devices shown in FIGS. 6B-6D are produced by forming the coupling portion 20 that connects the respective lower surfaces or the respective side surfaces of the silicon interposer portions 9, and then, placing the silicon interposer portions 9 over the upper surface of the resin substrate 6 via the bumps 4.

Given the variety of embodiments of the present invention just described, the above description and illustrations should not be taken as limiting the scope of the present invention defined by the claims.

While the invention has been particularly shown and described with reference to the preferred embodiments thereof, it will be understood by those skilled in the art that various changes in form and details may be made without departing from the sprit and scope of the invention. It is intended to cover various modifications and similar arrangements and procedures, and the scope of the appended claims therefore should be accorded the broadest interpretation so as to encompass all such modifications and similar arrangements and procedures.

A semiconductor device according to an example of the present invention is used in various types of electronic equipment using a plurality of semiconductor elements, such as mobile phones, personal computers, integrated circuit (IC) cards, personal digital assistants (PDAs), optical communication equipment, and medical equipment.

What is claimed is:

1. A stacked semiconductor device, comprising:
a first substrate;
a second substrate provided over the first substrate, and divided into a plurality of portions;
a cooling member provided in a gap between the divided second substrate portions on the first substrate; and
a third substrate provided on the second substrate portions and the cooling member.

2. The stacked semiconductor device of claim 1, further comprising:
a coupling portion for coupling respective upper surfaces, respective lower surfaces, the respective upper surfaces and the respective lower surfaces, or respective side surfaces of adjoining ones of the second substrate portions, which adjoin each other with the cooling member interposed therebetween.

3. The stacked semiconductor device of claim 1, wherein
the cooling member has a heat absorbing portion and a heat dissipating portion, and
a region that reaches a highest temperature in the third substrate is located at the same position as that of the heat absorbing portion.

4. The stacked semiconductor device of claim 3, wherein
an intersection of dividing lines that separate the second substrate portions from each other is located at the same position as that of the region that reaches the highest temperature in the third substrate.

5. The stacked semiconductor device of claim 1, wherein
the cooling member is a heat pipe.

6. The stacked semiconductor device of claim 1, wherein
the cooling member is formed by a heat pipe provided in a part of the dividing lines that separate the second substrate portions from each other, and a heat dissipating plate provided in the remaining part of the dividing lines.

7. A method for manufacturing a stacked semiconductor device, comprising the steps of:
(a) placing a plurality of second substrates over a first substrate with a gap between the plurality of second substrates;
(b) providing a cooling member in at least a part of the gap between the plurality of second substrates on the first substrate; and
(c) placing a third substrate on the plurality of second substrates and the cooling member.

8. The method of claim 7, wherein
the step (a) includes the steps of
(a1) forming a coupling portion that couples respective lower surfaces or respective side surfaces of adjoining ones of the plurality of second substrates to each other, and
(a2) placing the plurality of second substrates over the first substrate after the step (a1).

9. The method of claim 7, further comprising the step of:
after the step (b) and before the step (c), forming a coupling portion that couples respective upper surfaces of adjoining ones of the plurality of second substrates to each other.

10. The method of claim 7, wherein
the cooling member has a heat absorbing portion and a heat dissipating portion, and
in the step (c), the third substrate is placed so that a region that reaches a highest temperature in the third substrate is located at the same position as that of the heat absorbing portion.

11. The method of claim 7, wherein
the cooling member is a heat pipe.
